(19) United States
(12) Patent Application Publication
(10) Pub. No.: US 2025/0112388 A1
(43) Pub. Date: Apr. 3, 2025

(54) ELECTRICAL CONNECTOR

(71) Applicant: LOTES CO., LTD, Keelung (TW)

(72) Inventor: Kai-Quan Zhou, Keelung (TW)

(21) Appl. No.: 18/899,292

(22) Filed: Sep. 27, 2024

(30) Foreign Application Priority Data
Sep. 28, 2023 (CN) 202311273447.1

(51) Int. Cl. H01R 12/70

(52) U.S. Cl. CPC H01R 12/7076; H01R 12/7011

(57) ABSTRACT

The present invention discloses an electrical connector, which is used to be electrically connected to a chip module. The electrical connector includes: a base; a plurality of terminals, provided in the base; a pickup cover, covered above the base, and abutting downward against the base; and at least one counterweight block, positioned in at least one of the base and the pickup cover. The counterweight block does not interfere with the terminals. The electrical connector in the present invention is provided with the counterweight blocks and utilizes the counterweight blocks to increase the weight for pressing the base, thus resolving the issue of the warping of the base due to heat and reducing the ill soldering of the terminals when the electrical connector is soldered to a circuit board.

### CROSS-REFERENCE TO RELATED PATENT APPLICATION

This non-provisional application claims priority to and the benefit of, pursuant to 35 U.S.C. § 119(a), patent application Serial No. CN202311273447.1 filed in China on Sep. 28, 2023. The disclosure of the above application is incorporated herein in its entirety by reference.

Some references, which may include patents, patent applications and various publications, are cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference were individually incorporated by reference.

### FIELD

The present invention relates to an electrical connector, and particularly to an electrical connector electrically connecting a chip module and a circuit board.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

An existing electrical connector is used to connect a chip module to a circuit board. The electrical connector includes an insulating body, a plurality of terminals provided in the insulating body and a cover provided above the insulating body. The insulating body is provided with an accommodating cavity to accommodate the chip module. The terminals are provided in the insulating body and are electrically connected to the chip module in the accommodating cavity. The insulating body is substantially in a rectangular shape, and the terminals are provided on the rectangular surface thereof. However, when the terminals are soldered, the insulating body may be prone to upward or downward warping deformation. If the warping is severe, the flatness of the terminals may be deteriorated, leading to issues such as empty soldering or missed soldering of the terminals, which cannot perform normal electrical connection with the circuit board.

Therefore, a heretofore unaddressed need to design a new electrical connector exists in the art to address the aforementioned deficiencies and inadequacies.

### SUMMARY

To address the deficiencies in the related art, the present invention is directed to an electrical connector resolving the issue of the warping of the base due to heat and enhancing the soldering yield of the terminals.

To achieve the foregoing objective, the present invention provides an electrical connector, which is used to be electrically connected to a chip module. The electrical connector includes: a base, having four corners provided diagonally in pairs, wherein an intersection point of diagonals of the base is defined as a center point; a plurality of terminals, provided in the base; and a plurality of first counterweight blocks and a plurality of second counterweight blocks, all provided in the base, wherein the first counterweight blocks are provided around the center point and spaced apart from the terminals, a maximum enclosed boundary is defined by the first counterweight blocks, the second counterweight blocks are distributed outside the maximum enclosed boundary and spaced apart from the terminals, and the second counterweight blocks are provided at the four corners.

In certain embodiments, the base has a plurality of regions, each of the regions is distributed with a plurality of the terminals, a distance between two adjacent ones of the terminals in a same one of the regions is less than a distance between the terminals in different ones of the regions, a plurality of connecting bridges are provided between two adjacent ones of the regions, and a gap is provided between each two adjacent ones of the connecting bridges.

In certain embodiments, the base has a plurality of regions, each of the regions is distributed with a plurality of the terminals, each of the regions is provided with at least one third counterweight block, the third counterweight block is provided to be spaced apart from the terminals in a corresponding one of the regions, and the terminals in the corresponding one of the regions are provided to surround the third counterweight block.

In certain embodiments, the third counterweight block is located farther away from the center point than the first counterweight block, and is located closer to the center point than the second counterweight block.

In certain embodiments, the base has an accommodating cavity, the terminals protrudes upward into the accommodating cavity, the accommodating cavity is configured to accommodate the chip module, the base is provided with a plurality of regions corresponding to the accommodating cavity, each of the regions is distributed with a plurality of the terminals, the base is provided with a plurality of protruding walls corresponding to the four corners, the protruding walls are higher than the regions, the protruding walls are surroundingly provided outside the accommodating cavity, and the second counterweight blocks are located between the protruding walls and the terminals in adjacent ones of the regions.

In certain embodiments, each of the protruding walls has a first side wall extending along a front-rear direction and a second side wall extending along a left-right direction, the first side wall and the second side wall are connected to each other, the base has a first positioning protrusion protruding from the first side wall toward the accommodating cavity and a second positioning protrusion protruding from the second side wall toward the accommodating cavity, the first positioning protrusion and the second positioning protrusion are configured to position the chip module, and viewing from a top viewing angle, a corresponding one of the second counterweight blocks is provided to correspond to the first positioning protrusion in the left-right direction and to correspond to the second positioning protrusion in the front-rear direction.

In certain embodiments, the base is provided with a plurality of supporting portions protruding upward to support the chip module, and the first counterweight blocks and the second counterweight blocks are not higher than the supporting portions.

In certain embodiments, the base is provided with a central recess, the central recess runs vertically through the base, the center point is located in the central recess, the first counterweight blocks are provided to surround the central recess, the central recess defines a first center line and a second center line, one of the first counterweight blocks is provided at each of a front side and a rear side of the central recess along the first center line, and one of the first counterweight blocks is provided at each of a left side and a right side of the central recess along the second center line.

In certain embodiments, the terminals, the first counterweight blocks and the second counterweight blocks are made of metal materials, and a material of the first counterweight blocks and a material of the second counterweight blocks are different from a material of the terminals.

Compared to the related art, certain embodiments of the present invention have the following beneficial effects: the first counterweight blocks are provided around the center point intersected by the diagonals of the base and spaced apart from the terminals, the second counterweight blocks are distributed around peripheries of the first counterweight blocks and spaced apart from the terminals, and the second counterweight blocks are provided at the four corners at the periphery of the base. The first counterweight blocks and the second counterweight blocks are distributed on the base, and the counterweight blocks are provided at locations of the base prone to warping and deformation, thus increasing the weight of the electrical connector, reducing the warping of the base due to heat when the electrical connector is soldered to the circuit board, and enhancing the soldering yield of the terminals.

The present invention further provides an electrical connector, which is used to be electrically connected to a chip module. The electrical connector includes: a base, having an accommodating cavity configured to accommodate the chip module, wherein the base is provided with a plurality of matching portions at a periphery of the base; a plurality of terminals, provided in the base and exposed in the accommodating cavity; a pickup cover, covered above the base, wherein the pickup cover comprises a body portion and a plurality of coupling portions located at a periphery of the body portion, the body portion abuts downward against the base at least outside the accommodating cavity, the coupling portions match with the matching portions, the body portion comprises a bottom surface facing the base and a top surface away from the base, the body portion has a plurality of upper positioning slots downward concavely provided from the top surface and a plurality of lower positioning slots upward concavely provided from the bottom surface, the upper positioning slots and the lower positioning slots are provided one-to-one correspondingly, and the upper positioning slots and the corresponding lower positioning slots are provided vertically at intervals; and a plurality of counterweight blocks, comprising a plurality of upper counterweight blocks and a plurality of lower counterweight blocks, wherein the upper counterweight blocks are positioned in the upper positioning slots, the lower counterweight blocks are positioned in the lower positioning slots, the upper counterweight blocks and the vertically corresponding lower counterweight blocks are magnetically attracted to each other, and a bottom end of each of the lower counterweight blocks is provided to be higher than the terminals.

In certain embodiments, the base is divided into a plurality of regions corresponding to the accommodating cavity, the terminals are distributed in the regions, the base is provided with a plurality of protruding walls, the protruding walls are higher than the regions, the protruding walls are surroundingly provided outside the accommodating cavity, the body portion abuts downward against the protruding walls, and the upper counterweight blocks and the lower counterweight blocks are provided to correspond to the accommodating cavity in a vertical direction.

In certain embodiments, the pickup cover is provided with a plurality of first abutting posts protruding toward the base, the base is provided with a plurality of supporting portions and a plurality of receiving portions protruding upward in the regions, the first receiving portions are not higher than the supporting portions, and the first abutting posts abut against the first receiving portions.

In certain embodiments, the base has a central portion surroundingly formed by the regions, the central portion is not provided with the terminals, the central portion is provided with a plurality of second receiving portions, a height of each of the first receiving portions and a height of each of the second receiving portions are identical to a height of each of the supporting portions, the pickup cover is provided with a plurality of second abutting posts corresponding to the second receiving portions to abut against the second receiving portions.

Certain embodiments of the present invention have the following beneficial effects: the upper counterweight blocks are positioned in the first positioning slots of the pickup cover, the lower counterweight blocks are positioned in the second positioning slots of the pickup cover, and the upper counterweight blocks and the vertically corresponding lower counterweight blocks are magnetically attracted to each other. Thus, the upper counterweight blocks and the lower counterweight blocks are magnetically attracted to each other and positioned in the pickup cover, without the need of providing a fixing structure to fix the counterweight blocks. Further, by increasing the weight on the pickup cover, the weight is transferred to the base through the pickup cover, thus reducing the warping due to heat, and enhancing the soldering yield of the terminals.

The present invention further provides an electrical connector, which is used to be electrically connected to a chip module. The electrical connector includes: a base; a plurality of terminals, provided in the base; a pickup cover, covered above the base, and abutting downward against the base; and at least one counterweight block, positioned in at least one of the base and the pickup cover, wherein the counterweight block does not interfere with the terminals.

In certain embodiments, the electrical connector includes a plurality of counterweight blocks, the base is divided into a plurality of regions, a central portion surroundingly formed by the regions and a peripheral portion located outside the regions, each of the regions is distributed with a plurality of the terminals, the counterweight blocks comprise at least one first counterweight block, a plurality of second counterweight blocks and a plurality of third counterweight blocks, the first counterweight block is provided in the central portion, the second counterweight blocks are provided in the peripheral portion along a periphery of the central portion, and each of the regions is provided with at least one of the third counterweight blocks.

In certain embodiments, the electrical connector includes a plurality of counterweight blocks, the base is divided into a plurality of regions, a central portion surroundingly formed by the regions and a peripheral portion located outside the regions, each of the regions is distributed with a plurality of the terminals, the counterweight blocks comprise a plurality of first counterweight blocks and a plurality of second counterweight blocks, the central portion is provided with the first counterweight blocks along a periphery of a center thereof, and the second counterweight blocks are provided in the peripheral portion along a periphery of the central portion.

In certain embodiments, the electrical connector includes a plurality of counterweight blocks, at least one of the base and the pickup cover is provided with a plurality of positioning slots, and the counterweight blocks are detachably mounted in the positioning slots.

In certain embodiments, the pickup cover comprises a body portion, the body portion comprises a bottom surface facing the base and a top surface away from the base, the counterweight blocks are located on at least one of the top surface and the bottom surface, the base is divided into a plurality of regions, each of the regions is distributed with a plurality of the terminals, a plurality of connecting bridges are provided between two adjacent ones of the regions, a gap is provided between each two adjacent ones of the connecting bridges, each of the regions is provided with a first receiving portion, the base has a central portion surroundingly formed by the regions, the central portion is not provided with the terminals, the central portion is provided with a plurality of second receiving portions, and at least some of the second receiving portions are provided on some of the connecting bridges; and the pickup cover has a plurality of first protruding posts and a plurality of second protruding posts formed by protruding from the bottom surface, the first protruding posts correspondingly abut against the first receiving portions, and the second protruding posts correspondingly abut against the second receiving portions.

In certain embodiments, the base has an accommodating cavity, at least one first position limiting slot and at least one first recess located outside the accommodating cavity in a left-right direction, and at least one second position limiting slot and at least one second recess located outside the accommodating cavity in a front-rear direction, and the accommodating cavity, the first position limiting slot, the first recess, the second position limiting slot and the second recess all run upward through the base; and the pickup cover has a body portion and at least one first positioning post, at least one first guiding post, at least one second position post and at least one second guiding post formed by protruding downward from a periphery of the body portion, the first positioning post protrudes into the first position limiting slot such that the pickup cover is precisely positioned on the base in the front-rear direction, the second positioning post protrudes into the second position limiting slot such that the pickup cover is precisely positioned on the base in the left-right direction, the first guiding post is accommodated in the first recess, a size of the first guiding post in the front-rear direction is less than a size of the first recess in the left-right direction, the first guiding post has a moving space in the first recess for moving along the front-rear direction, the second guiding post is accommodated in the second recess, a size of the second guiding post in the left-right direction is less than a size of the second recess in the left-right direction, and the second guiding post has a moving space in the second recess for moving along the left-right direction.

In certain embodiments, the base has two first position limiting slots, two first recesses, two second position limiting slots and two second recesses, the base has four first side walls extending along the front-rear direction and four second side walls extending along the left-right direction surrounding outside the accommodating cavity, each of the first side walls is connected to one of the second side walls, each of the first side walls and the one of the second side walls connected to each other form a corner at a connecting location thereof, the four first side walls and the four second side walls are two-to-two connected to form four corners, the four corners are provided diagonally in pairs, for two corners in each pair of the four corners provided diagonally, the first side wall corresponding to one of the two corners is concavely provided with one of the two first position limiting slots, the second side wall corresponding to the one of the two corners is concavely provided with one of the two second position limiting slots, the first side wall corresponding to the other of the two corners is concavely provided with one of the two first recesses, the second side wall corresponding to the other of the two corners is concavely provided with one of the two second recesses, one of the two first side walls provided opposite to each other along in the left-right direction is provided with one of the two first position limiting slots, the two first position limiting slots are provided to be opposite to each other along the left-right direction, one of the two second side walls provided opposite to each other along in the front-rear direction is provided with one of the two second position limiting slots, and the two second position limiting slots are provided to be opposite to each other along the front-rear direction.

Compared to the related art, certain embodiments of the present invention have the following beneficial effects: at least one counterweight block is positioned in one of the base and the pickup cover, and the electrical connector is provided with the counterweight block, utilizing the counterweight block to increase the weight and to press the base, thus reducing the warping due to heat when the electrical connector is soldered to a circuit board, and enhancing the soldering yield of the terminals.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIG. 1 is a perspective view of an electrical connector and a circuit board according to a first embodiment of the present invention.

FIG. 2 is an exploded view of the electrical connector and the circuit board in FIG. 1.

FIG. 3 is a partially enlarged view of a portion A in FIG. 2.

FIG. 4 is a partially enlarged view of a portion B in FIG. 2.

FIG. 5 is a partially enlarged view of a portion C in FIG. 2.

FIG. 6 is a top view of the electrical connector in FIG. 2 after removing the pickup cover.

FIG. 7 is a partially enlarged view of a portion D in FIG. 6.

FIG. 8 is a sectional view of FIG. 6 sectioned along line E-E.

FIG. 9 is a schematic view of the electrical connector in FIG. 3 being installed into a chip module.

FIG. 10 is a perspective view of a terminal in FIG. 2.

FIG. 11 is a perspective view of the pickup cover in FIG. 1 from another viewing angle.

FIG. 12 is a perspective view of an electrical connector and a circuit board according to a second embodiment of the present invention.

FIG. 13 is a partially enlarged view of a portion F in FIG. 12.

FIG. 14 is a partially enlarged view of a portion G in FIG. 12.

FIG. 15 is a perspective assembly view of FIG. 12.

FIG. 16 is a perspective sectional view of the electrical connector in FIG. 15 sectioned along line H-H.

FIG. 17 is a sectional view of the electrical connector in FIG. 15 sectioned along line I-I.

FIG. 18 is a partial sectional view of the electrical connector in FIG. 15 sectioned along line J-J.

FIG. 19 is a partial sectional view of the electrical connector in FIG. 15 removing the pickup cover and sectioned along line J-J after the electrical connector is installed in a chip module.

FIG. 20 is a perspective view of the pickup cover in FIG. 12 from another viewing angle.

FIG. 21 is a top view of the base of the electrical connector and the pickup cover after matching and sectioning according to certain embodiments of the present invention.

### DETAILED DESCRIPTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the terms “comprising”, “including”, “carrying”, “having”, “containing”, “involving”, and the like are to be understood to be open-ended, i.e., to mean including but not limited to.

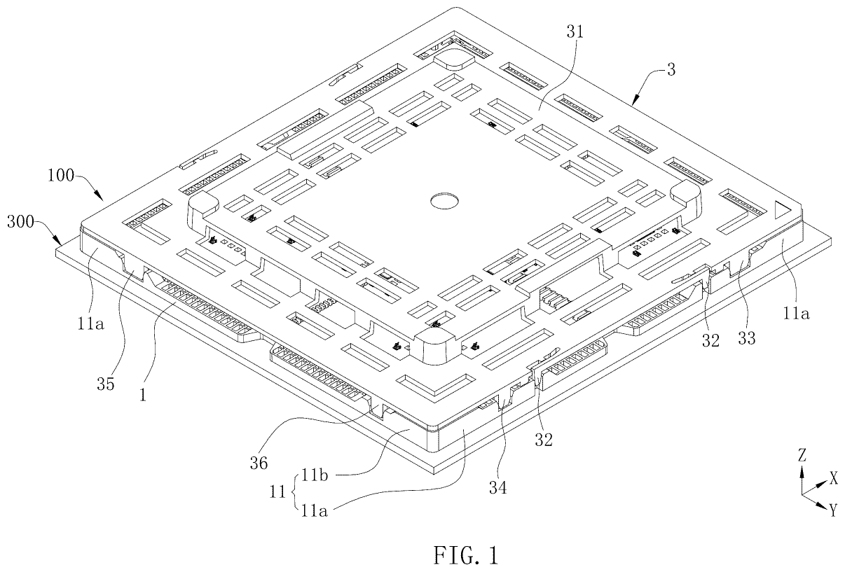

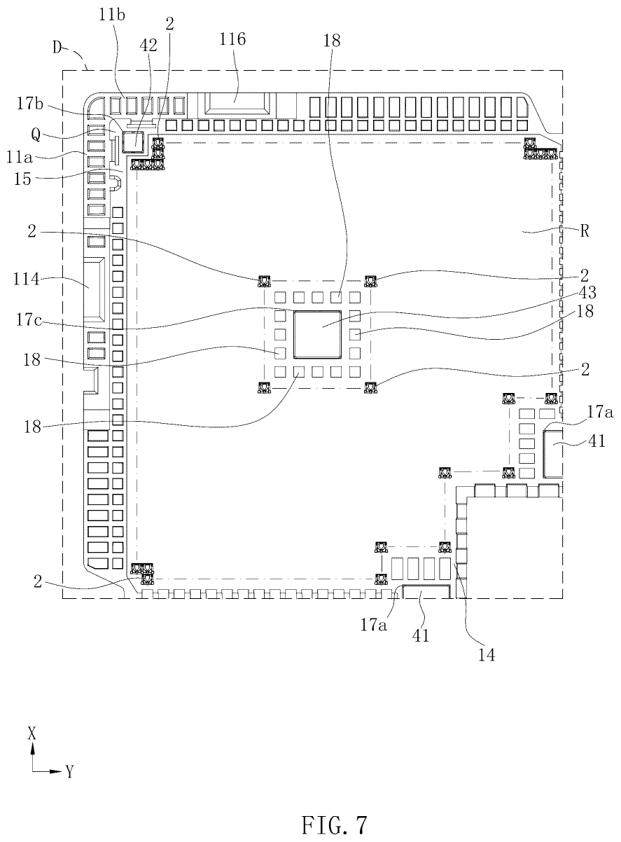

The description will be made as to the embodiments of the present invention in conjunction with the accompanying drawings in FIGS. 1-21. In accordance with the purposes of this invention, as embodied and broadly described herein, this invention, in one aspect, relates to an electrical connector.

For ease of understanding, a front-rear direction is defined as the X-axis, a left-right direction is defined as the Y-axis, a vertical direction is defined as the Z-axis, and any two of the three directions are perpendicular to each other.

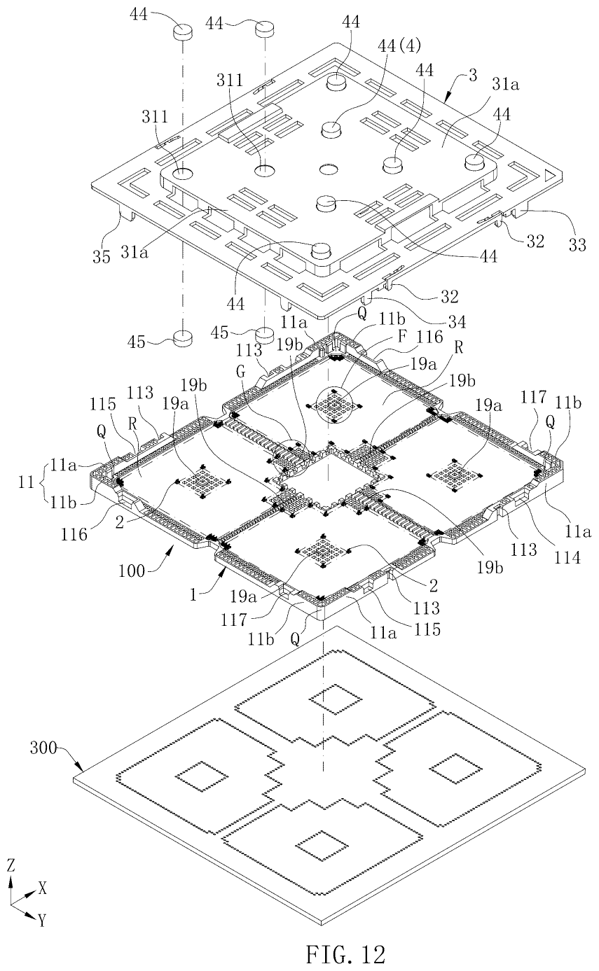

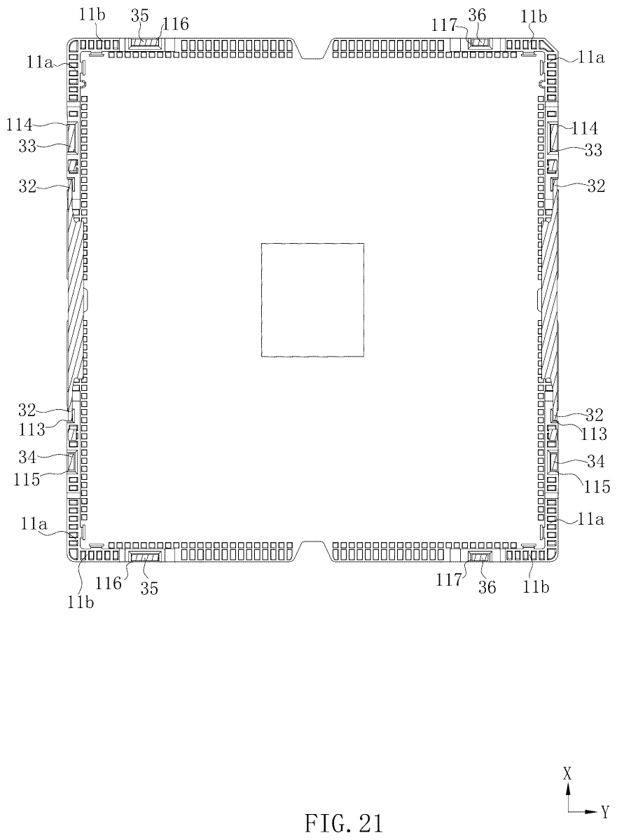

FIG. 1 to FIG. 21 show embodiments of the present invention. FIG. 1 to FIG. 11 show an electrical connector 100 according to a first embodiment of the present invention, and FIG. 12 to FIG. 20 show an electrical connector 100 according to a second embodiment of the present invention. In the first and second embodiments, the electrical connector 100 is used to electrically connect a chip module 200 to a circuit board 300. The electrical connector 100 includes: a base 1, a plurality of terminals 2 provided in the base 1, a pickup cover 3 provided to cover the base 1 and a plurality of counterweight blocks 4. FIG. 21 is a schematic view of the base 1 and the pickup cover 3 after matching and sectioning according to the first embodiment and the second embodiment of the present invention.

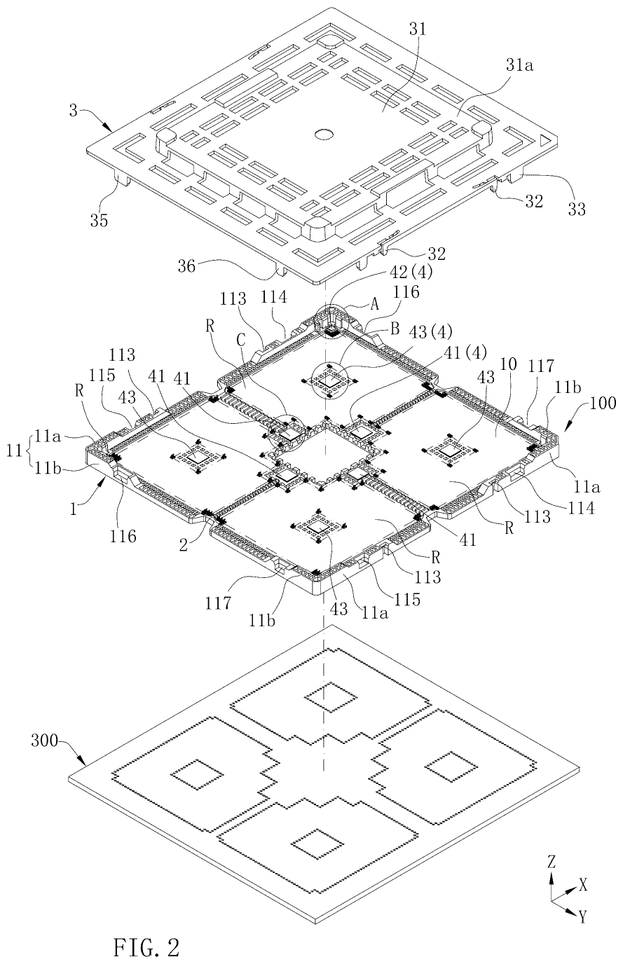

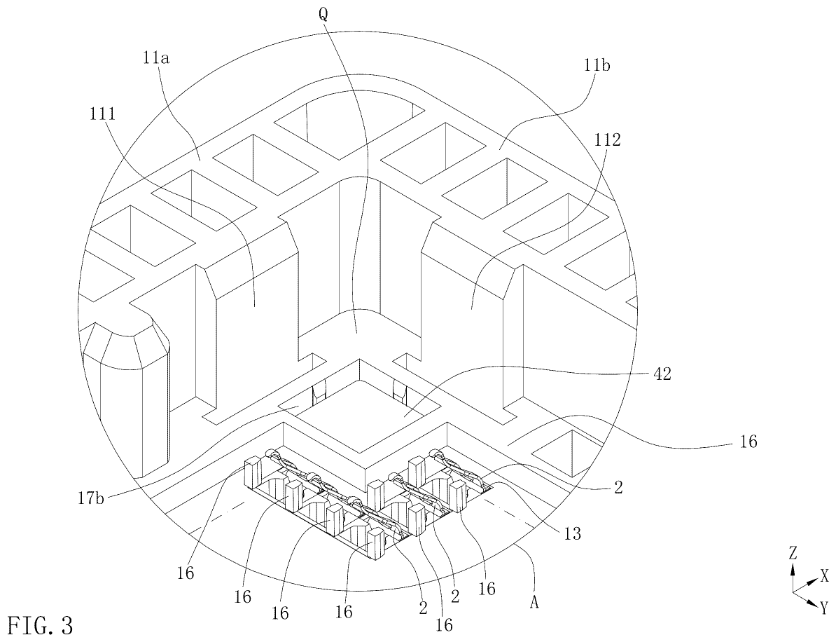

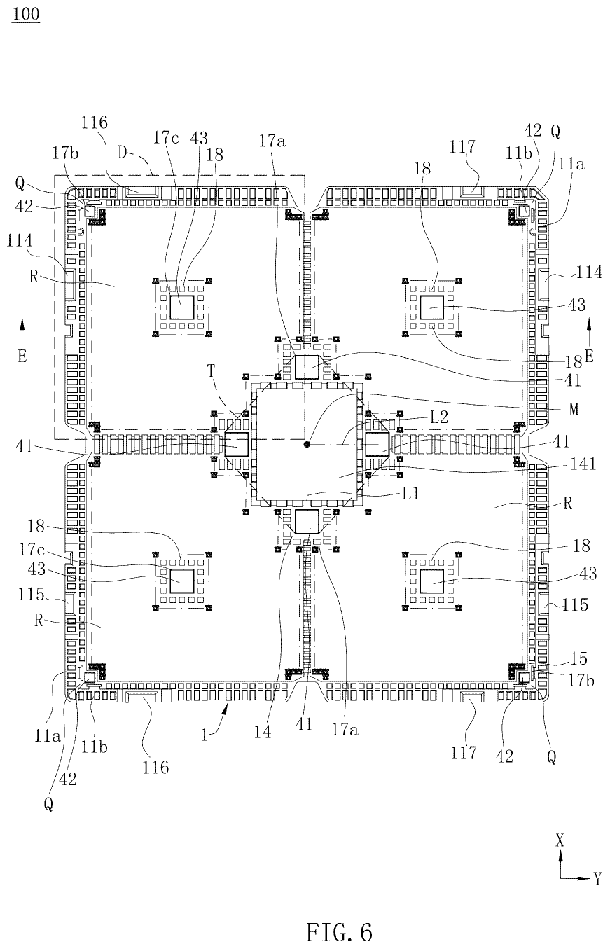

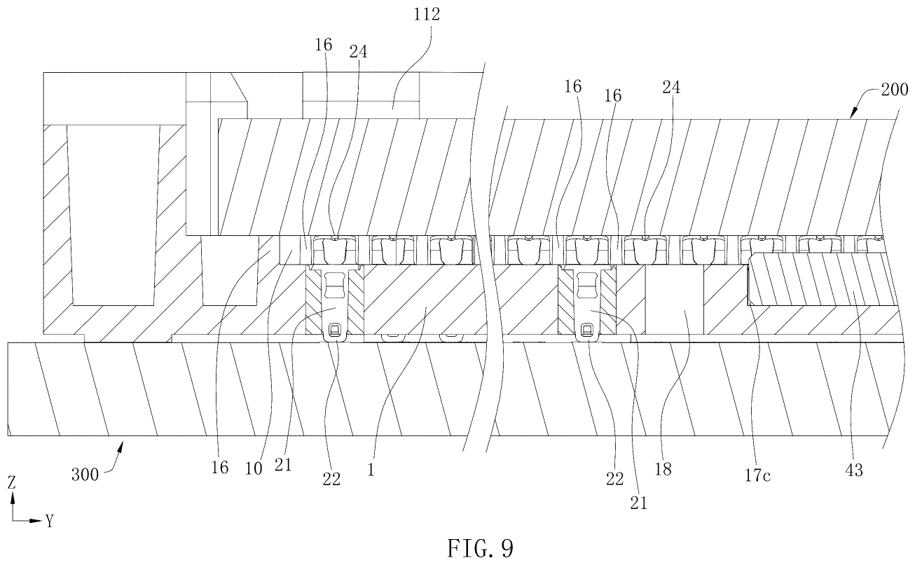

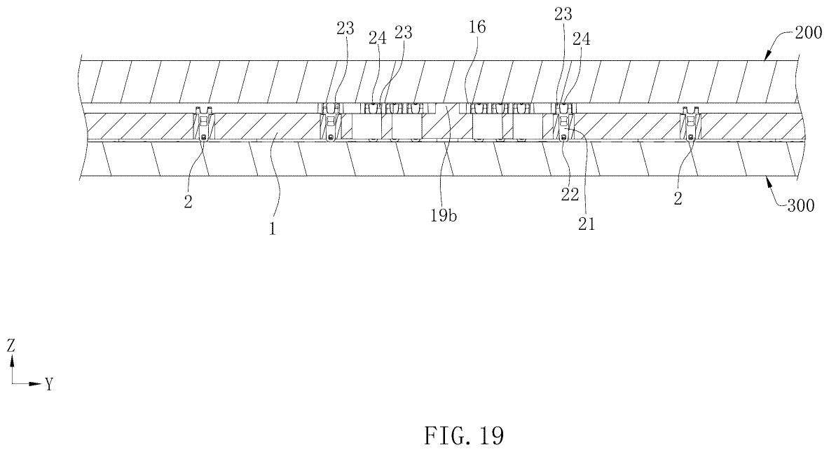

As shown in FIG. 2, FIG. 3, FIG. 6 and FIG. 12, in the first and second embodiments, the base 1 has an accommodating cavity 10 running upward through the base 1, and the accommodating cavity 10 is used to accommodate the chip module 200 (also referring to FIG. 9 and FIG. 19). The base 1 is provided with a plurality of protruding walls 11 at the periphery of the accommodating cavity 10. In the present embodiment, viewing downward from top thereof, the base 1 is substantially in a rectangular shape, and four protruding walls 11 are provided. The base 1 has four corners Q provided diagonally in pairs, and each protruding wall 11 corresponds to one of the corners Q. Each protruding wall 11 includes a first side wall 11a extending along a front-rear direction and a second side wall 11b extending along a left-right direction, and the first side wall 11a and the second side wall 11b are connected to each other. The first side wall 11a is provided with a first positioning protrusion 111 protruding toward the accommodating cavity 10, and the second side wall 11b is provided with a second positioning protrusion 112 protruding toward the accommodating cavity 10. The first positioning protrusion 111 and the second positioning protrusion 112 are used to position the chip module 200. An outer side surface of at least one of the first side wall 11a and the second side wall 11b away from the accommodating cavity 10 is concavely provided with a matching portion 113 to match with the pickup cover 3. In the first and second embodiments, the matching portion 113 is provided on the first side wall 11a. The base 1 has two of the first side walls 11a at each side of the periphery of the accommodating cavity 10 along the left-right direction. For the two first side walls 11a located at the same side, an outer side surface of one of the first side walls 11a away from the accommodating cavity 10 is concavely provided with a first position limiting slot 114, and an outer side surface of the other of the first side walls 11a away from the accommodating cavity 10 is concavely provided with a first recess 115. The base 1 has two of the second side walls 11b at each side of the periphery of the accommodating cavity 10 along the front-rear direction. For the two second side walls 11b located at the same side, an outer side surface of one of the second side walls 11b away from the accommodating cavity 10 is concavely provided with a second position limiting slot 116, and an outer side surface of the other of the second side walls 11b away from the accommodating cavity 10 is concavely provided with a second recess 117.

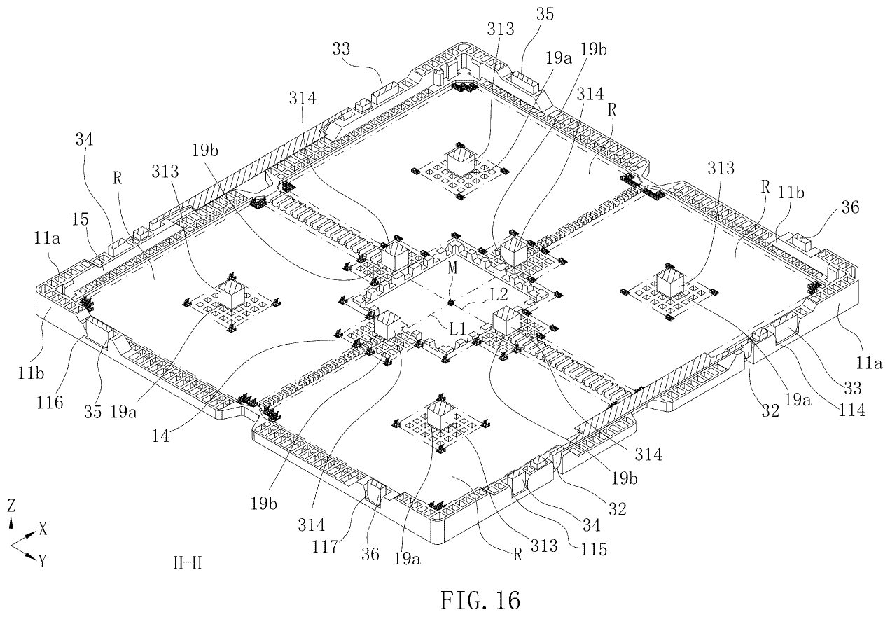

As shown in FIG. 6 and FIG. 16, in the first and second embodiments, the base 1 is divided into a plurality of regions R, and the regions R are located inside the protruding walls 11. That is, the regions R correspond to the location below the accommodating cavity 10. A plurality of connecting bridges 12 are provided between each two adjacent regions R, and each two adjacent connecting bridges 12 are provided to be spaced apart. The connecting bridges 12 are provided to be higher than the regions R. In other embodiments, the connecting bridges 12 and the regions R may be provided to have an equal height, or the connecting bridges 12 are provided to be lower than the regions R. Each region R is provided with a plurality of terminal holes to accommodate the terminals 2.

As shown in FIG. 6 and FIG. 12, in the first and second embodiments, the base 1 has a central portion 14 and a peripheral portion 15. The central portion 14 is surroundingly formed by the regions R, and the peripheral portion 15 is located outside the regions R. Thus, the central portion 14 and the peripheral portion 15 are not provided with the terminals 2. A central location of the central portion 14 is concavely provided with a central recess 141, and the central recess 141 runs vertically through the base 1. The central recess 141 has a first center line L1 extending along the front-rear direction and a second center line L2 extending along the left-right direction. An intersection point of the diagonals of the base 1 is defined as a center point M, and the center point M is located in the central recess 141. The peripheral portion 15 includes the four corners Q. In other embodiments, the central portion 14 of the base 1 may be provided with the regions R distributed with the terminals 2.

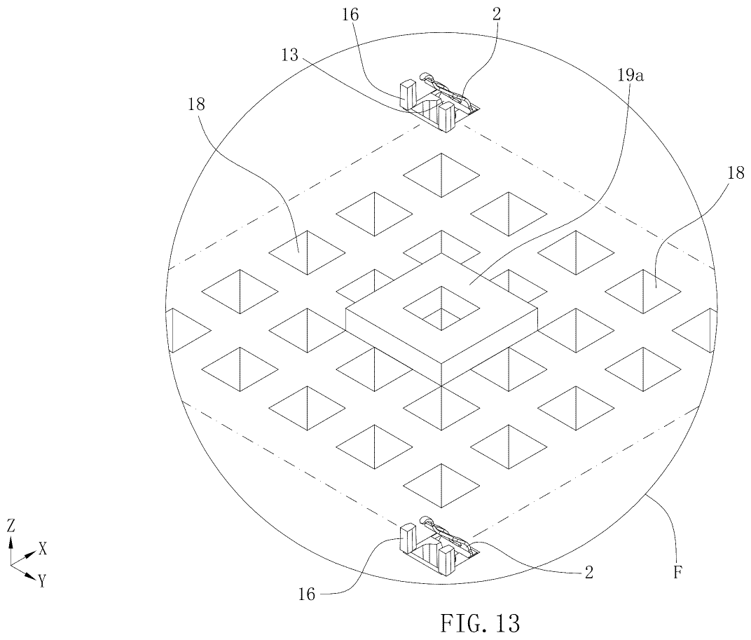

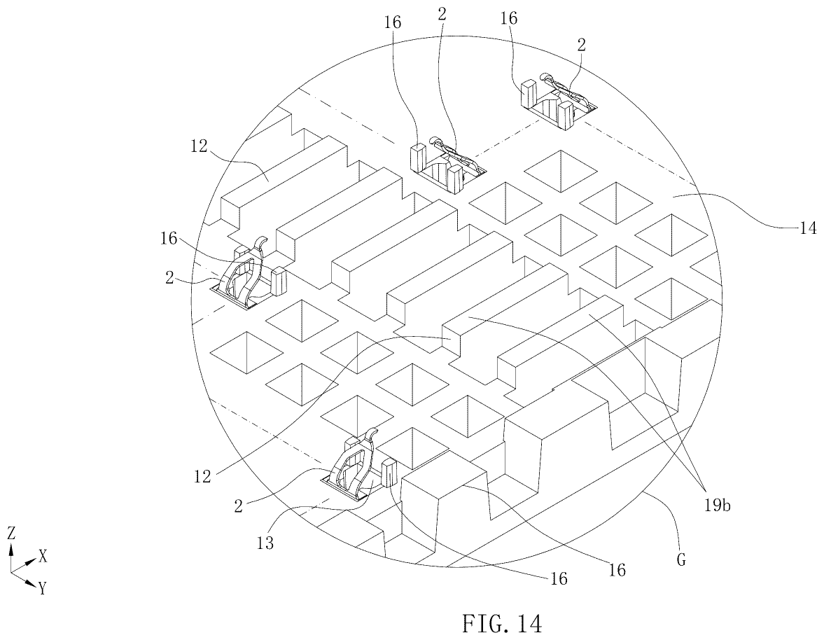

As shown in FIG. 3 to FIG. 5, FIG. 13 and FIG. 14, in the first and second embodiments, the base 1 is provided with a plurality of supporting portions 16 corresponding to the accommodating cavity 10. Some of the supporting portions 16 are provided to correspond to the regions R, and the supporting portions 16 corresponding to one of the regions R are located at the sides of the terminal holes 13 of the one of the regions R. Some others of the supporting portions 16 are provided in the periphery portion 15, and the remaining ones of the supporting portions 16 are provided in the central portion 14. When the chip module 200 has not be installed into the accommodating cavity 10, the supporting portions 16 are lower than the terminals 2 in a vertical direction. When the chip module 200 is installed into the accommodating cavity 10, the portions of the terminals 2 being in contact with the chip module 200 are pressed downward by the chip module 200 and move downward until the supporting portions 16 support the chip module 200, thus preventing the chip module 200 from excessively pressing downward the terminals 2 and damaging the terminals 2 (also referring to FIG. 9 and FIG. 19).

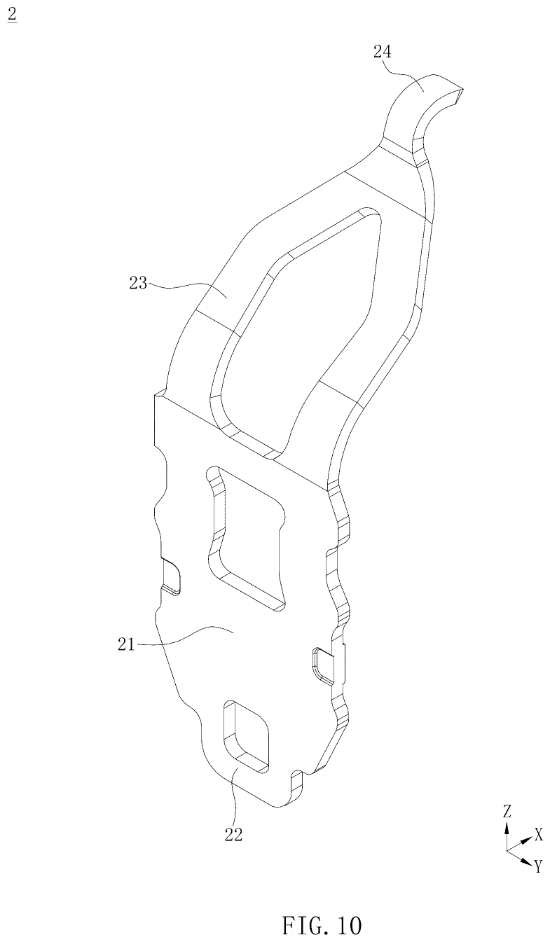

As shown in FIG. 9, FIG. 10 and FIG. 19, in the first and second embodiments, the terminals 2 are made of a metal material, and each terminal 2 includes a vertical portion 21, a soldering portion 22 located below the vertical portion 21, an elastic portion 23 located above the vertical portion 21 and a contact portion 24 extending from the elastic portion 23. The vertical portion 21 is accommodated in a corresponding terminal hole 13. The soldering portion 22 is a surface provided below the vertical portion 21 and facing downward to be surface-soldered to the circuit board 300. The contact portion 24 is used to be electrically connected to the chip module 200.

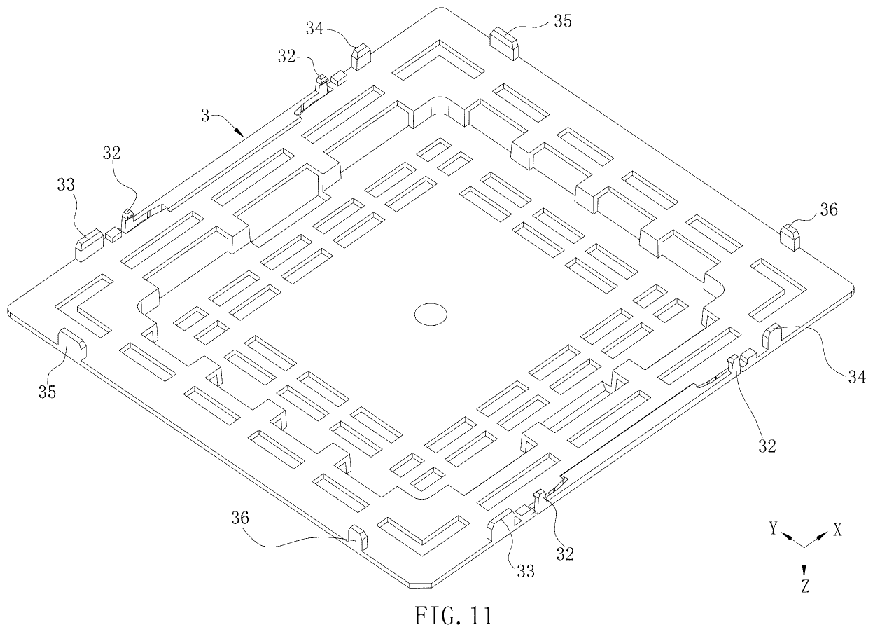

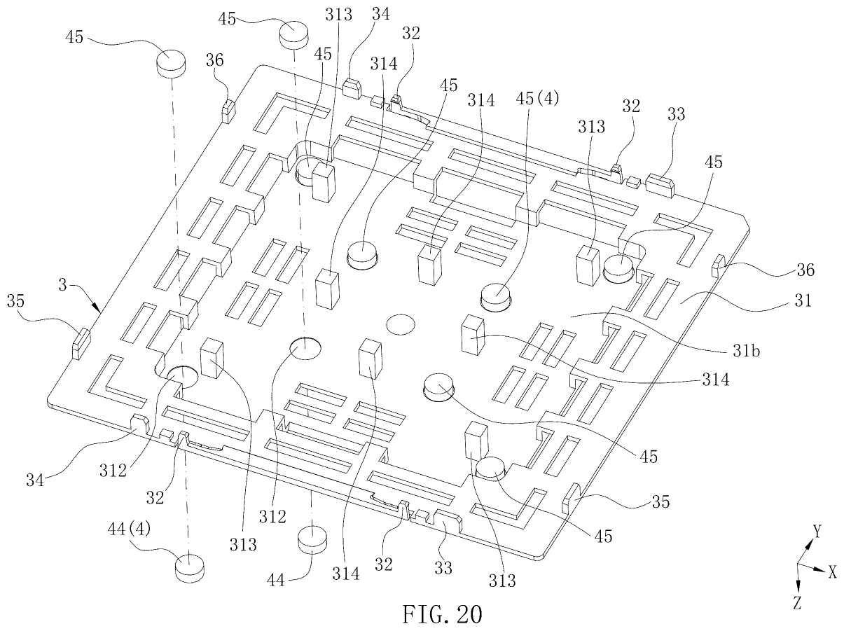

As shown in FIG. 1, FIG. 11, FIG. 12 and FIG. 20, in the first and second embodiments, a peripheral contour of the pickup cover 3 is substantially a rectangular structure, and the pickup cover 3 is provided to cover above the base 1. The pickup cover 3 abuts downward against the base 1. The pickup cover 3 includes a body portion 31 and a plurality of coupling portions 32, a plurality of first positioning posts 33, a plurality of first guiding posts 34, a plurality of second positioning posts 35 and a plurality of second guiding posts 36 located around the body portion 31 and formed by protruding downward. The coupling portions 32 and the matching portions 113 match with each other through clamping, such that the pickup cover 3 does not easily detach from the base 1. Two first positioning posts 33 are provided, and the two first positioning posts 33 are provided to be spaced apart and opposite to each other along the left-right direction. Two first guiding posts 34 are provided, and the two first guiding posts 34 are provided to be spaced apart and opposite to each other along the left-right direction. Two second positioning posts 35 are provided, and the two second positioning posts 35 are provided to be spaced apart and opposite to each other along the front-rear direction. Two second guiding posts 36 are provided, and the two second guiding posts 36 are provided to be spaced apart and opposite to each other along the front-rear direction. The body portion 31 includes a bottom surface 31b facing the base 1 and a top surface 31a away from the base 1.

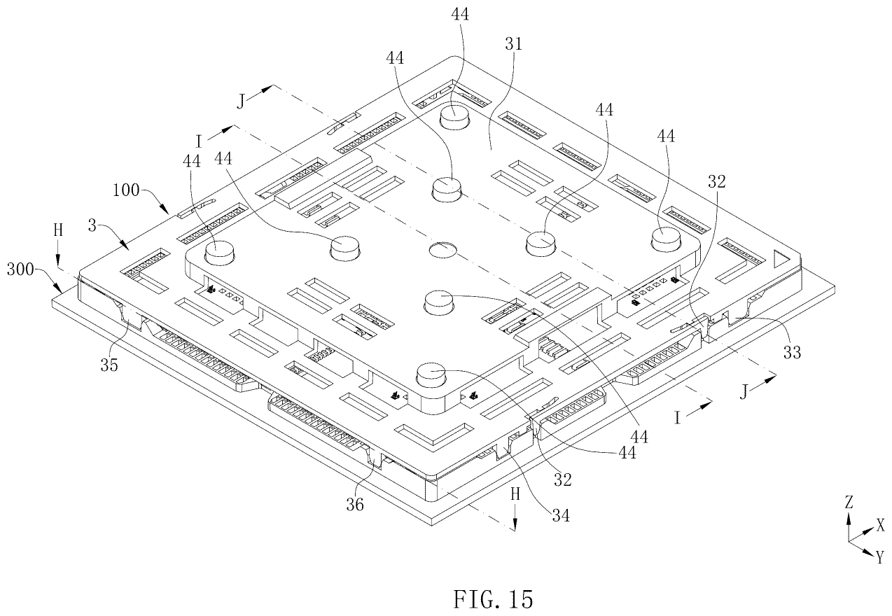

As shown in FIG. 1, FIG. 15 and FIG. 21, in the first and second embodiments, the two first guiding posts 34 are one-to-one correspondingly accommodated the two first recesses 115, and the two second guiding posts 36 are one-to-one correspondingly accommodated the two second recesses 117. The two first positioning posts 33 are one-to-one correspondingly accommodated the two first position limiting slots 114, such that the pickup cover 3 is precisely positioned to the base 1 in the front-rear direction. The two second positioning posts 35 are one-to-one correspondingly accommodated the two second position limiting slots 116, such that the pickup cover 3 is precisely positioned to the base 1 in the left-right direction. Thus, the precise positioning of the pickup cover 3 in the left-right direction and the front-rear direction is facilitated, such that the matching of the pickup cover 3 and the base 1 is more stable, without being loosened from the base 1 in the left-right direction and the front-rear direction, thereby preventing from the case where the pickup cover 3 causes the base 1 to inaccurately align with the circuit board 300. Since the pickup cover 3 is to be installed to the base 1, installation gaps exist between the first positioning posts 33 and the first position limiting slots 114 in the front-rear direction and between the second positioning posts 35 and the second position limiting slots 116 in the front-rear direction. The installation gaps are very small and do not affect precise positioning. In the present embodiment, each installation gap is 0.05 mm. In other embodiments, it is possible to provide only one first positioning post 33 and only one second positioning post 35, or to provide more quantities of the first positioning posts 33 and the second positioning posts 35.

As shown in FIG. 11, FIG. 20 and FIG. 21, in the first and second embodiments, for the first positioning post 33 and the first guiding post 34 located at the same side of the pickup cover 3 in the left-right direction, the first positioning post 33 and the first guiding post 34 are provided to be spaced apart in the front-rear direction. A size of the first positioning post 33 in the front-rear direction is greater than a size of the first guiding post 34 in the front-rear direction, and the size of the first guiding post 34 in the front-rear direction is less than a size of the first recess 115 in the front-rear direction. The first guiding post 34 has a moving space in the corresponding first recess 115 for moving along the front-rear direction. Preferably, in the design, the first guiding post 34 is centrally accommodated in the corresponding first recess 115 in the front-rear direction. The pickup cover 3 and the base 1 are prone to warping and deformation due to heat in the forming process, which may cause deviations of the sizes of the pickup cover 3 and the base 1 in the front-rear direction, such that it may be difficult for the pickup cover 3 to be assembled into the base 1 in the front-rear direction. The moving space provides a buffer space for the deviations of the sizes, allowing the pickup cover 3 to be smoothly assembled into the base 1 after forming.

As shown in FIG. 21, in the first and second embodiments, for the second positioning post 35 and the second guiding post 36 located at the same side of the pickup cover 3 in the front-rear direction, the second positioning post 35 and the second guiding post 36 are provided to be spaced apart in the left-right direction. A size of the second positioning post 35 in the left-right direction is greater than a size of the second guiding post 36 in the left-right direction, and the size of the second guiding post 36 in the left-right direction is less than a size of the corresponding second recess 117 in the left-right direction. The second guiding post 36 has a moving space in the corresponding second recess 117 for moving along the left-right direction. Preferably, in the design, the second guiding post 36 is centrally accommodated in the corresponding second recess 117 in the left-right direction. Similarly, the moving space may buffer the difficulties of assembly caused by the deviations of the sizes of the pickup cover 3 and the base 1 in the left-right direction resulted in warping and deformation of the pickup cover 3 and the base 1 due to heat in the forming process.

As shown in FIG. 3 to FIG. 6, in the first embodiment, the base 1 is provided with a plurality of positioning slots. The positioning slots are downward concavely provided on an upper surface of the base 1 corresponding to the accommodating cavity 10, and do not run downward through the base 1. Some of the positioning slots are distributed in the central portion 14, and these positioning slots located in the central portion 14 are defined as first positioning slots 17a. Some others of the positioning slots are distributed in the peripheral portion 15, and these positioning slots located in the peripheral portion 15 are defined as second positioning slots 17b. Still some others of the positioning slots are distributed in the regions R, and these positioning slots located in the regions R are defined as third positioning slots 17c. Four first positioning slots 17a are provided in the central portion 14 around the central recess 141 and are spaced apart from two adjacent regions R. One of the four first positioning slots 17a is provided at each of the front side and the rear side of the central recess 141 along the first center line L1 and at each of the left side and the right side of the central recess 141 along the second center line L2. The second positioning slots 17b are distributed outside of the first positioning slots 17a and provided at the corners Q. Specifically, each corner Q is provided with one of the second positioning slots 17b, and each second positioning slot 17b is located between the corresponding protruding wall 11 and the adjacent region R. A plurality of third positioning slots 17c are provided, and each region R is provided with at least one third positioning slots 17c. Viewing from the top viewing angle, the terminals 2 surround the third positioning slots 17c and are spaced apart from the third positioning slots 17c.

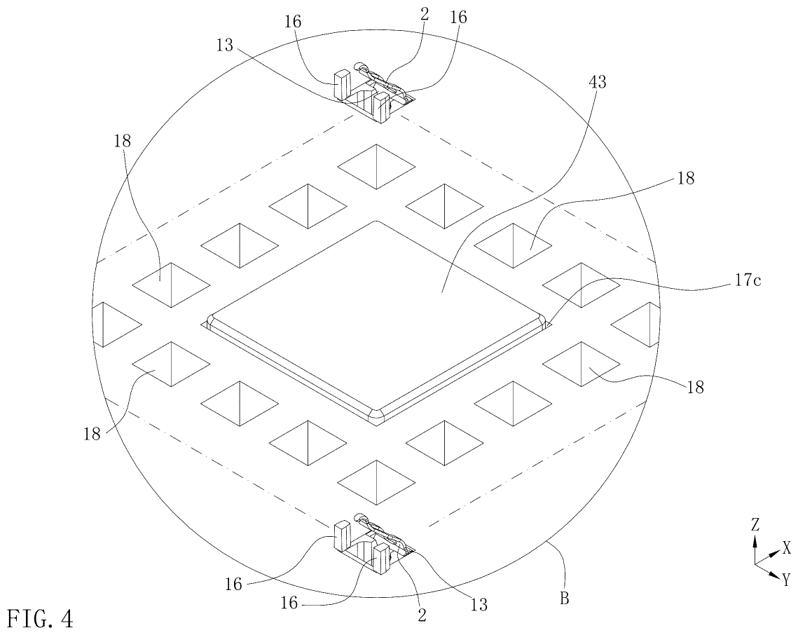

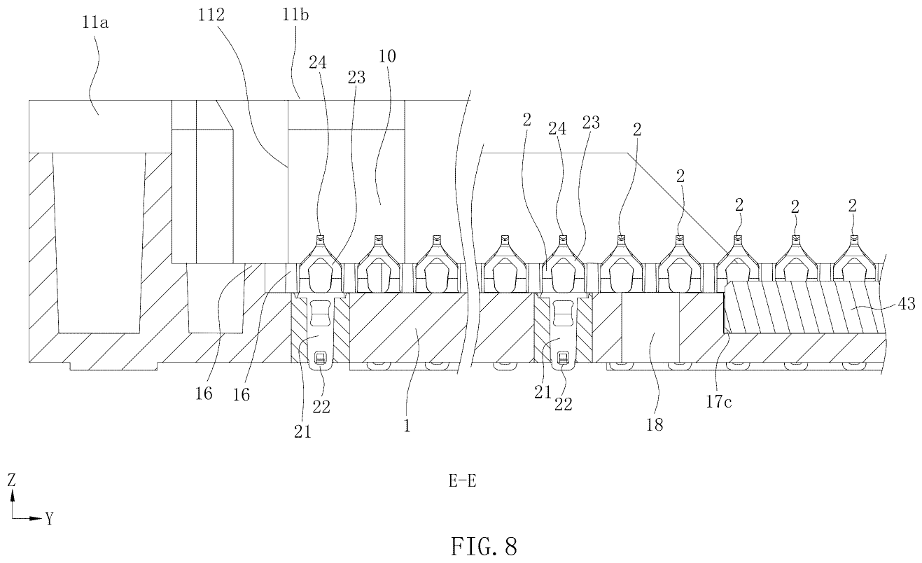

As shown in FIG. 4 and FIG. 8, in the first embodiment, each region R is further provided with a plurality of opening holes 18, and the opening holes 18 run vertically through the base 1. Viewing from a top viewing angle, the opening holes 18 are provided around the third positioning slots 17c, and the terminals 2 in the corresponding region R surround the corresponding opening holes 18.

As shown in FIG. 2, FIG. 6 and FIG. 9, in the first embodiment, the counterweight blocks 4 are made of a metal material and provided in the positioning slots of the base 1, and the metal material of the counterweight blocks 4 and the metal material of the terminals 2 are different. In the present embodiment, the counterweight blocks 4 are detachably mounted in the corresponding positioning slots. Thus, after the electrical connector 100 is soldered to the circuit board 300, the counterweight blocks 4 may be detached. In other embodiments, the counterweight blocks 4 may be embedded in the base 1, or may be mounted in the corresponding positioning slots and form a tight fit with the corresponding positioning slots.

As shown in FIG. 2 and FIG. 6, in the first embodiment, the counterweight blocks 4 include a plurality of first counterweight blocks 41, a plurality of second counterweight blocks 42 and a plurality of third counterweight blocks 43.

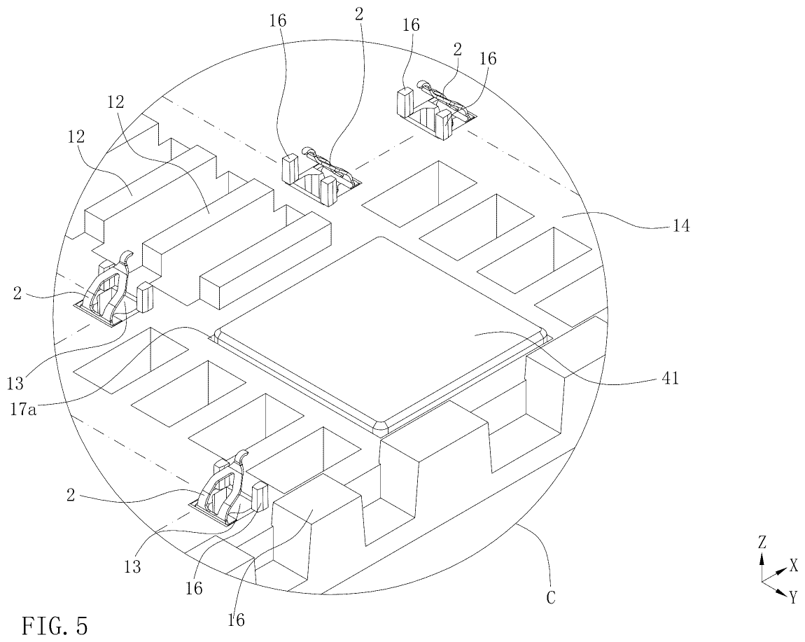

As shown in FIG. 5, FIG. 6 and FIG. 9, in the first embodiment, the first counterweight blocks 41 are provided around the center point M and spaced apart from the terminals 2. Four first counterweight blocks 41 are provided, and the four first counterweight blocks 41 are one-to-one correspondingly received in the four first positioning slots 17a. One of the four first counterweight blocks 41 are provided at each of the front side, the rear side, the left side and the right side of the central recess 141. Each first counterweight block 41 is spaced apart from the terminals 2, and the first counterweight blocks 41 are not higher than the supporting portions 16. Specifically, the first counterweight blocks 41 are provided to be lower than the supporting portions 16. In other embodiments, quantities of the first positioning slots 17a and the corresponding first counterweight blocks 41 may be provided according to the need, and the quantities of the first positioning slots 17a and the corresponding first counterweight blocks 41 may be less than four, or even only one, or may be more than four. The first counterweight blocks 41 and the supporting portions 16 may be provided to have an equal height.

As shown in FIG. 3 and FIG. 6, in the first embodiment, the second counterweight blocks 42 are distributed at peripheries of the first counterweight blocks 41. Viewing from the top viewing angle, the second counterweight blocks 42 are provided in the peripheral portion 15 and spaced apart from the terminals 2 at the peripheries of the adjacent regions R. The second counterweight blocks 42 are provided to correspond to the first positioning protrusions 111 in the left-right direction and to correspond to the second positioning protrusions 112 in the front-rear direction. The second positioning slots 17b are concavely provided at the corners Q. Specifically, four second counterweight blocks 42 are provided, and the four second counterweight blocks 42 are one-to-one received in the four second positioning slots 17b at the four corners Q. Due to the space limitation, the second counterweight blocks 42 are smaller than the first counterweight blocks 41. The second counterweight blocks 42 are not higher than the supporting portions 16. Specifically, the second counterweight blocks 42 are provided to be lower than the supporting portions 16. In other embodiments, quantities of the second positioning slots 17b and the corresponding second counterweight blocks 42 may be provided according to the need, and the quantities of the second positioning slots 17b and the corresponding second counterweight blocks 42 may be less than four or may be more than four. The second counterweight blocks 42 are provided to distributedly surround the center point M around the peripheral portion 15, and it is possible that some of the four corners Q are provided with the corresponding second positioning slots 17b and the corresponding second counterweight blocks 42. The second counterweight blocks 42 and the supporting portions 16 may be provided to have an equal height.

As shown in FIG. 4, FIG. 6 and FIG. 9, in the first embodiment, the third counterweight blocks 43 are one-to-one received in the third positioning slots 17c of the regions R, and the terminals 2 in the regions R are provided to surround the corresponding third counterweight blocks 43. Each third counterweight block 43 is provided to be spaced apart from the terminals 2 in the corresponding region R, and the opening holes 18 are provided on the base 1 and located between the third counterweight blocks 43 and the surrounding adjacent terminals 2. The third counterweight blocks 43 are located farther away from the center point M relative to the first counterweight blocks 41, and are located closer to the center point M relative to the second counterweight blocks 42. The third counterweight blocks 43 are not higher than the supporting portions 16. Specifically, the third counterweight blocks 43 are provided to be lower than the supporting portions 16. In other embodiments, each region R may be provided with a plurality of the third positioning slots 17c. In other words, a plurality of third counterweight blocks 43 may be provided in each region R. The third counterweight blocks 43 and the supporting portions 16 may be provided to have an equal height.

As shown in FIG. 12, FIG. 13 and FIG. 14, in the second embodiment, the base 1 is provided with a first receiving portion 19a in each region R, and each first receiving region 19a is not higher than the supporting portions 16. Specifically, the first receiving portions 19a and the supporting portions 16 are of the same height. Each first receiving portion 19a is surrounded by the terminals 2 provided in the corresponding region R. The base 1 between each first receiving portion 19a and the terminals 2 is provided with a plurality of opening holes 18, and the opening holes 18 surround the first receiving portion 19a to separate the terminals 2 and the first receiving portion 19a. In other embodiments, the first receiving portions 19a may be provided to be lower than the supporting portions 16.

As shown in FIG. 12, FIG. 13, FIG. 14 and FIG. 16, in the second embodiment, the central portion 14 is provided with a plurality of second receiving portions 19b, and the second receiving portions 19b are provided at the front side and the rear side of the central recess 141 along the first center line L1 and at the left side and the right side of the central recess 141 along the second center line L2. Each second receiving portion 19b is provided to be spaced apart from the adjacent region R, and the second receiving portions 19b are provided on some of the connecting bridges 12. Specifically, the portions of the connecting bridges 12 correspondingly provided in the central portion 14 and protruding upward from the regions R serve as the second receiving portions 19b. The second receiving portions 19b are provided not to be higher than the supporting portion 16. Specifically, the second receiving portions 19b and the supporting portions 16 are provided to have an equal height. In other embodiments, some of the second receiving portions 19b may be provided on some of the connecting bridges 12. Alternatively, it is also possible that the second receiving portions 19b are not provided on the connecting bridges 12.

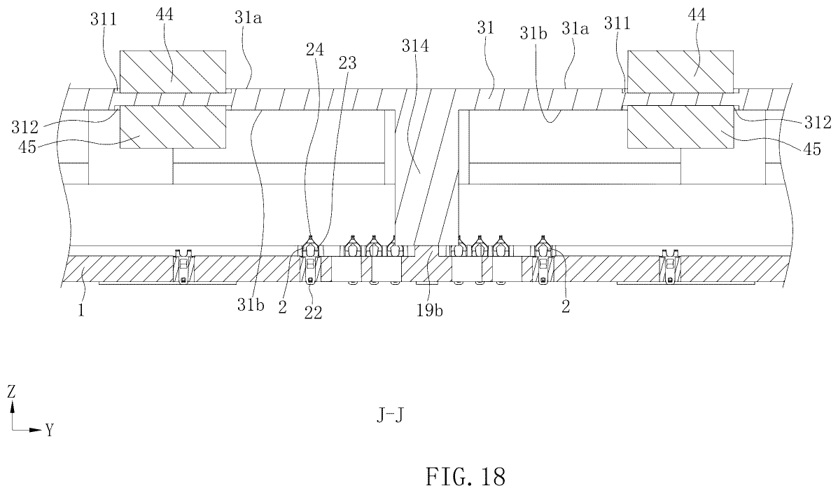

As shown in FIG. 12, FIG. 18 and FIG. 20, in the second embodiment, the body portion 31 is provided with a plurality of positioning slots, and the counterweight blocks 4 are detachably mounted in the positioning slots. The positioning slots include a plurality of upper positioning slots 311 downward concavely provided from the top surface 31a and a plurality of lower positioning slots 312 upward concavely provided from the bottom surface 31b. The upper positioning slots 311 and the lower positioning slots 312 are one-to-one vertically provided correspondingly, and the upper positioning slots 311 and the corresponding lower positioning slots 312 are provided to be vertically spaced apart.

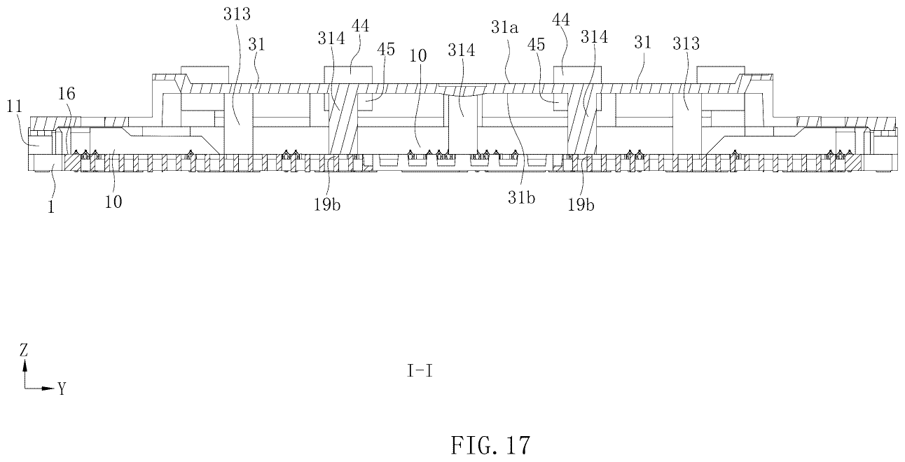

As shown in FIG. 16, FIG. 17, FIG. 18 and FIG. 20, in the second embodiment, the pickup cover 3 is provided with a plurality of first abutting posts 313 and a plurality of second abutting posts 314 protruding toward the base 1 from the bottom surface 31b. The first abutting posts 313 are provided to form a circle, and the second abutting posts 314 are also provided to form a circle. The circle formed by the first abutting posts 313 is located outside of the circle formed by the second abutting posts 314, and the first abutting posts 313 and the second abutting posts 314 all abut against the base 1. Specifically, the first abutting posts 313 abut against the first receiving portions 19a, and the second abutting posts 314 abut against the second receiving portions 19b.

As shown in FIG. 12, FIG. 18 and FIG. 20, in the second embodiment, the counterweight blocks 4 include a plurality of upper counterweight blocks 44 and a plurality of lower counterweight blocks 45. The upper counterweight blocks 44 are one-to-one correspondingly positioned in the upper positioning slots 311, and the lower counterweight blocks 45 are one-to-one correspondingly positioned in the lower positioning slots 312. The upper counterweight blocks 44 and the vertically corresponding lower counterweight blocks 45 are magnetically attracted to each other, and bottom ends of the lower counterweight blocks 45 are provided to be higher than the terminals 2. Thus, of the upper counterweight blocks 44 and the lower counterweight blocks 45, one is made of a magnet, and the other is made of a magnetic material that may be attracted by the magnet. Alternatively, both of the upper counterweight blocks 44 and the lower counterweight blocks 45 may be made of magnets. In other embodiments, it is possible that the upper counterweight blocks 44 and the lower counterweight blocks 45 are not made of magnetic materials, and are mounted on the pickup cover 3 by fixing structures. The counterweight blocks 4 are provided on at least one of the top surface 31a and the bottom surface 31b of the pickup cover 3, and it is possible that the counterweight blocks 4 are embedded in the pickup cover 3 by insert-molding technology. In another embodiment, it is possible not to provide a plurality of counterweight blocks 4, and only one counterweight block 4 is provided on the top surface 31a.

In sum, the electrical connector according to certain embodiments of the present invention has the following beneficial effects:

1. The first counterweight blocks 41, the second counterweight blocks 42 and the third counterweight blocks 43 are all provided at different locations of the base 1. The first counterweight blocks 41 are provided around the center point M, the second counterweight blocks 42 are distributed around peripheries of the first counterweight blocks 41 and provided at the four corners Q, and the third counterweight blocks 43 are located between the first counterweight blocks 41 and the second counterweight blocks 42. The counterweight blocks 4 are provided at locations of the base 1 prone to warping and deformation, thus increasing the overall weight of the electrical connector 100, reducing the warping of the base 1 due to heat when the electrical connector 100 is soldered to the circuit board 300, and enhancing the soldering yield of the terminals 2.

2. The base 1 is provided with the opening holes 18 located between the third counterweight blocks 43 and the surrounding adjacent terminals 2, such that the third counterweight blocks 43 and the terminals 2 are spaced apart, thus reducing the interference to the terminals 2 by the third counterweight blocks 43. The opening holes 18 allow the base 1 to have a uniform thickness during insert-molding, thus reducing the warping of the base 1 during insert-molding, reducing the strength of the base 1, and reducing the warping of the base 1 generated in the process of the electrical connector 100 being soldered to the circuit board 300.

3. The upper counterweight blocks 44 and the lower counterweight blocks 45 are made of magnetic materials and are detachably mounted in the upper positioning slots 311 and the lower positioning slots 312. The upper counterweight blocks 44 and the lower counterweight blocks 45 may be used repeatedly, thus reducing the manufacturing cost of the electrical connector 100.

4. The first abutting posts 313 and the second abutting posts 314 all abut against the base 1, and the first abutting posts 313 are provided outside of the second abutting posts 314, such that the pickup cover 3 applies forces distributedly on the base 1, reducing the warping of the base 1 generated in the process of the electrical connector 100 being soldered to the circuit board 300.

5. The base 1 has a plurality of regions R, and each region R is distributed with a plurality of terminals 2. A plurality of connecting bridges 12 are provided between two adjacent regions R, and a gap is provided between each two adjacent connecting bridges 12, thus reducing the strength of the base 1, and reducing the warping of the base 1 generated in the process of the electrical connector 100 being soldered to the circuit board 300.

6. The base 1 has the first side walls 11a extending along the front-rear direction and the second side walls 11b extending along the left-right direction. The first side walls 11a and the second side walls 11b are connected to each other. Each first side wall 11a is provided with a first positioning protrusion 111 protruding toward the accommodating cavity 10 and corresponds to a corresponding second counterweight block 42 in the left-right direction, and each second side wall 11b is provided with a second positioning protrusion 112 protruding toward the accommodating cavity 10 and corresponds to a second counterweight block 42 in the front-rear direction to position the chip module 200. Further, the second counterweight blocks 42 are provided at the corners Q of the base 1, thus reducing the upward warping of the edges of the base 1.

7. The first receiving portions 19a and the second receiving portions 19b are not higher than the supporting portions 16, thus preventing the chip module 200 from not pressing on the supporting portions 16 and preventing from insufficient downward pressing movement of the terminals 2. The first receiving portions 19a, the second receiving portions 19b and the supporting portions 16 are of the same height. When the chip module 200 is mounted on the base 1, the first receiving portions 19a and the second receiving portions 19b may be used to support the chip module 200, thus preventing the chip module 200 from excessively pressing downward and damaging the terminals 2.

8. By precisely positioning the first positioning posts 33 of the pickup cover 3 in the first position limiting slots 114 of the base 1 in the front-rear direction, and precisely positioning the second positioning posts 35 of the pickup cover 3 in the second position limiting slots 116 of the base 1 in the left-right direction, position limiting in the two directions are facilitated, such that the pickup cover 3 does not move in the left-right direction and the front-rear direction after being assembled to the base 1. When the pickup cover 3 is sucked by vacuum to move the electrical connector 100 to a location matching with the circuit board 300, the pickup cover 3, due to the facilitation of the position limiting in the two directions, does not loosen from the base 1, thereby facilitating precise positioning of the electrical connector 100 and the circuit board 300. By providing the size of each first guiding post 34 to be less than the size of the first recess 115, the first guiding post 34 has a moving space in the first recess 115 for moving along the front-rear direction, and by providing the size of each second guiding post 36 to be less than the size of the second recess 117, the second guiding post 36 has a moving space in the second recess 117 for moving along the left-right direction, such that in the forming process, at least one of the pickup cover 3 and the base 1 is not subjected to deformation caused by thermal expansion and contraction that leads to failure of mounting the pickup cover 3 into the base 1.

9. By providing the size of the first positioning posts 33 in the front-rear direction to be greater than the size of the first guiding posts 34 in the front-rear direction, and the size of the second positioning posts 35 in the left-right direction to be greater than the size of the second guiding posts 35 in the left-right direction, the two posts at the same side are provided to include a larger one and a smaller one, thus achieving the foolproof effect, preventing the pickup cover 3 to be mounted reversely.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. An electrical connector, configured to be electrically connected to a chip module, the electrical connector comprising:
a base, having four corners provided diagonally in pairs, wherein an intersection point of diagonals of the base is defined as a center point;
a plurality of terminals, provided in the base; and
a plurality of first counterweight blocks and a plurality of second counterweight blocks, all provided in the base, wherein the first counterweight blocks are provided around the center point and spaced apart from the terminals, a maximum enclosed boundary is defined by the first counterweight blocks, the second counterweight blocks are distributed outside the maximum enclosed boundary and spaced apart from the terminals, and the second counterweight blocks are provided at the four corners.

2. The electrical connector according to claim 1, wherein the base has a plurality of regions, each of the regions is distributed with a plurality of the terminals, a distance between two adjacent ones of the terminals in a same one of the regions is less than a distance between the terminals in different ones of the regions, a plurality of connecting bridges are provided between two adjacent ones of the regions, and a gap is provided between each two adjacent ones of the connecting bridges.

3. The electrical connector according to claim 1, wherein the base has a plurality of regions, each of the regions is distributed with a plurality of the terminals, each of the regions is provided with at least one third counterweight block, the third counterweight block is provided to be spaced apart from the terminals in a corresponding one of the regions, and the terminals in the corresponding one of the regions are provided to surround the third counterweight block.

4. The electrical connector according to claim 3, wherein the third counterweight block is located farther away from the center point than the first counterweight block, and is located closer to the center point than the second counterweight block.

5. The electrical connector according to claim 1, wherein the base has an accommodating cavity, the terminals protrudes upward into the accommodating cavity, the accommodating cavity is configured to accommodate the chip module, the base is provided with a plurality of regions corresponding to the accommodating cavity, each of the regions is distributed with a plurality of the terminals, the base is provided with a plurality of protruding walls corresponding to the four corners, the protruding walls are higher than the regions, the protruding walls are surroundingly provided outside the accommodating cavity, and the second counterweight blocks are located between the protruding walls and the terminals in adjacent ones of the regions.

6. The electrical connector according to claim 5, wherein each of the protruding walls has a first side wall extending along a front-rear direction and a second side wall extending along a left-right direction, the first side wall and the second side wall are connected to each other, the base has a first positioning protrusion protruding from the first side wall toward the accommodating cavity and a second positioning protrusion protruding from the second side wall toward the accommodating cavity, the first positioning protrusion and the second positioning protrusion are configured to position the chip module, and viewing from a top viewing angle, a corresponding one of the second counterweight blocks is provided to correspond to the first positioning protrusion in the left-right direction and to correspond to the second positioning protrusion in the front-rear direction.

7. The electrical connector according to claim 1, wherein the base is provided with a plurality of supporting portions protruding upward to support the chip module, and the first counterweight blocks and the second counterweight blocks are not higher than the supporting portions.

8. The electrical connector according to claim 1, wherein the base is provided with a central recess, the central recess runs vertically through the base, the center point is located in the central recess, the first counterweight blocks are provided to surround the central recess, the central recess defines a first center line and a second center line, one of the first counterweight blocks is provided at each of a front side and a rear side of the central recess along the first center line, and one of the first counterweight blocks is provided at each of a left side and a right side of the central recess along the second center line.

9. The electrical connector according to claim 1, wherein the terminals, the first counterweight blocks and the second counterweight blocks are made of metal materials, and a material of the first counterweight blocks and a material of the second counterweight blocks are different from a material of the terminals.

10. An electrical connector, configured to be electrically connected to a chip module, the electrical connector comprising:
a base, having an accommodating cavity configured to accommodate the chip module, wherein the base is provided with a plurality of matching portions at a periphery of the base;
a plurality of terminals, provided in the base and exposed in the accommodating cavity;
a pickup cover, covered above the base, wherein the pickup cover comprises a body portion and a plurality of coupling portions located at a periphery of the body portion, the body portion abuts downward against the base at least outside the accommodating cavity, the coupling portions match with the matching portions, the body portion comprises a bottom surface facing the base and a top surface away from the base, the body portion has a plurality of upper positioning slots downward concavely provided from the top surface and a plurality of lower positioning slots upward concavely provided from the bottom surface, the upper positioning slots and the lower positioning slots are provided one-to-one correspondingly, and the upper positioning slots and the corresponding lower positioning slots are provided vertically at intervals; and
a plurality of counterweight blocks, comprising a plurality of upper counterweight blocks and a plurality of lower counterweight blocks, wherein the upper counterweight blocks are positioned in the upper positioning slots, the lower counterweight blocks are positioned in the lower positioning slots, the upper counterweight blocks and the vertically corresponding lower counterweight blocks are magnetically attracted to each other, and a bottom end of each of the lower counterweight blocks is provided to be higher than the terminals.

11. The electrical connector according to claim 10, wherein the base is divided into a plurality of regions corresponding to the accommodating cavity, the terminals are distributed in the regions, the base is provided with a plurality of protruding walls, the protruding walls are higher than the regions, the protruding walls are surroundingly provided outside the accommodating cavity, the body portion abuts downward against the protruding walls, and the upper counterweight blocks and the lower counterweight blocks are provided to correspond to the accommodating cavity in a vertical direction.

12. The electrical connector according to claim 11, wherein the pickup cover is provided with a plurality of first abutting posts protruding toward the base, the base is provided with a plurality of supporting portions and a plurality of receiving portions protruding upward in the regions, the first receiving portions are not higher than the supporting portions, and the first abutting posts abut against the first receiving portions.

13. The electrical connector according to claim 12, wherein the base has a central portion surroundingly formed by the regions, the central portion is not provided with the terminals, the central portion is provided with a plurality of second receiving portions, a height of each of the first receiving portions and a height of each of the second receiving portions are identical to a height of each of the supporting portions, the pickup cover is provided with a plurality of second abutting posts corresponding to the second receiving portions to abut against the second receiving portions.

14. An electrical connector, configured to be electrically connected to a chip module, the electrical connector comprising:
a base;
a plurality of terminals, provided in the base;
a pickup cover, covered above the base, and abutting downward against the base; and
at least one counterweight block, positioned in at least one of the base and the pickup cover, wherein the counterweight block does not interfere with the terminals.

15. The electrical connector according to claim 14, comprising a plurality of counterweight blocks, wherein the base is divided into a plurality of regions, a central portion surroundingly formed by the regions and a peripheral portion located outside the regions, each of the regions is distributed with a plurality of the terminals, the counterweight blocks comprise at least one first counterweight block, a plurality of second counterweight blocks and a plurality of third counterweight blocks, the first counterweight block is provided in the central portion, the second counterweight blocks are provided in the peripheral portion along a periphery of the central portion, and each of the regions is provided with at least one of the third counterweight blocks.

16. The electrical connector according to claim 14, comprising a plurality of counterweight blocks, wherein the base is divided into a plurality of regions, a central portion surroundingly formed by the regions and a peripheral portion located outside the regions, each of the regions is distributed with a plurality of the terminals, the counterweight blocks comprise a plurality of first counterweight blocks and a plurality of second counterweight blocks, the central portion is provided with the first counterweight blocks along a periphery of a center thereof, and the second counterweight blocks are provided in the peripheral portion along a periphery of the central portion.

17. The electrical connector according to claim 14, comprising a plurality of counterweight blocks, wherein at least one of the base and the pickup cover is provided with a plurality of positioning slots, and the counterweight blocks are detachably mounted in the positioning slots.

18. The electrical connector according to claim 17, wherein:
the pickup cover comprises a body portion, the body portion comprises a bottom surface facing the base and a top surface away from the base, the counterweight blocks are located on at least one of the top surface and the bottom surface, the base is divided into a plurality of regions, each of the regions is distributed with a plurality of the terminals, a plurality of connecting bridges are provided between two adjacent ones of the regions, a gap is provided between each two adjacent ones of the connecting bridges, each of the regions is provided with a first receiving portion, the base has a central portion surroundingly formed by the regions, the central portion is not provided with the terminals, the central portion is provided with a plurality of second receiving portions, and at least some of the second receiving portions are provided on some of the connecting bridges; and
the pickup cover has a plurality of first protruding posts and a plurality of second protruding posts formed by protruding from the bottom surface, the first protruding posts correspondingly abut against the first receiving portions, and the second protruding posts correspondingly abut against the second receiving portions.

19. The electrical connector according to claim 14, wherein:
the base has an accommodating cavity, at least one first position limiting slot and at least one first recess located outside the accommodating cavity in a left-right direction, and at least one second position limiting slot and at least one second recess located outside the accommodating cavity in a front-rear direction, and the accommodating cavity, the first position limiting slot, the first recess, the second position limiting slot and the second recess all run upward through the base; and
the pickup cover has a body portion and at least one first positioning post, at least one first guiding post, at least one second position post and at least one second guiding post formed by protruding downward from a periphery of the body portion, the first positioning post protrudes into the first position limiting slot such that the pickup cover is precisely positioned on the base in the front-rear direction, the second positioning post protrudes into the second position limiting slot such that the pickup cover is precisely positioned on the base in the left-right direction, the first guiding post is accommodated in the first recess, a size of the first guiding post in the front-rear direction is less than a size of the first recess in the left-right direction, the first guiding post has a moving space in the first recess for moving along the front-rear direction, the second guiding post is accommodated in the second recess, a size of the second guiding post in the left-right direction is less than a size of the second recess in the left-right direction, and the second guiding post has a moving space in the second recess for moving along the left-right direction.

20. The electrical connector according to claim 19, wherein the base has two first position limiting slots, two first recesses, two second position limiting slots and two second recesses, the base has four first side walls extending along the front-rear direction and four second side walls extending along the left-right direction surrounding outside the accommodating cavity, each of the first side walls is connected to one of the second side walls, each of the first side walls and the one of the second side walls connected to each other form a corner at a connecting location thereof, the four first side walls and the four second side walls are two-to-two connected to form four corners, the four corners are provided diagonally in pairs, for two corners in each pair of the four corners provided diagonally, the first side wall corresponding to one of the two corners is concavely provided with one of the two first position limiting slots, the second side wall corresponding to the one of the two corners is concavely provided with one of the two second position limiting slots, the first side wall corresponding to the other of the two corners is concavely provided with one of the two first recesses, the second side wall corresponding to the other of the two corners is concavely provided with one of the two second recesses, one of the two first side walls provided opposite to each other along in the left-right direction is provided with one of the two first position limiting slots, the two first position limiting slots are provided to be opposite to each other along the left-right direction, one of the two second side walls provided opposite to each other along in the front-rear direction is provided with one of the two second position limiting slots, and the two second position limiting slots are provided to be opposite to each other along the front-rear direction.
